(19) United States
(12) Patent Application Publication
(10) Pub. No.: US 2018/0108871 A1
(43) Pub. Date: Apr. 19, 2018

(54) MANUFACTURING METHOD FOR LED DISPLAY PANEL AND LED DISPLAY PANEL

(71) Applicant: Shenzhen China Star Optoelectronics Technology Co., Ltd., Shenzhen, Guangdong (CN)

(72) Inventor: Chao XU, Shenzhen, Guangdong (CN)

(73) Assignee: Shenzhen China Star Optoelectronics Technology Co., Ltd., Shenzhen, Guangdong (CN)

(21) Appl. No.: 15/109,404

(22) PCT Filed: May 26, 2016
(86) PCT No.: PCT/CN2016/083559

§ 371 Date: Jun. 30, 2016

(30) Foreign Application Priority Data
Apr. 15, 2016 (CN) 201610234902.0

(51) Int. Cl. H01L 51/56; H01L 51/00

(52) U.S. Cl. CPC H01L 51/56; H01L 51/0014; H01L 51/5056; H01L 51/0005; H01L 51/0012

(57) ABSTRACT

A manufacturing method for an LED display panel is disclosed. The method includes: forming a first electrode on a substrate; forming a function layer in the first electrode; through a nanoimprint method, forming multiple grooves on a surface of the function layer away from the first electrode; filling a luminescent solution in the multiple grooves in order to form an organic light-emitting layer; and forming a second electrode on the organic light-emitting layer. According to the manufacturing method for an LED display panel of the present invention, the manufacturing process can be simplified, the production cost can be decreased and the production yield can be effectively improved. The present invention also provides an LED display panel.

### CROSS REFERENCE

The claims of this application have submitted to the State Intellectual Property Office of the People's Republic of China (SIPO) on Apr. 15, 2016, Application No. 201610234902.0. The priority right based on the China application has a title of “Manufacturing method for LED display panel and LED display panel”. The entire contents of the above-mentioned patent application will be incorporated in the present application through citing.

### FIELD OF THE INVENTION

The present invention relates to a field of quantum dot light emitting diode, and more particularly to a manufacturing method for LED display panel and an LED display panel.

### BACKGROUND OF THE INVENTION

The quantum dot (abbreviated to QD) is a nanoparticle formed by II-VI group, III-V group or IV-VI group element. After the quantum dot is excited, the quantum dot can emit light. The wavelength of the emitted light of the quantum dot is related to the size of the quantum dot particle. Therefore, through controlling the size of the quantum dot, various visible lights having ideal wavelengths are generated. Besides, the quantum dot luminescent material has advantages of high color purity, high luminescence quantum efficiency, long life and so on such that the quantum dot is an electroluminescent material having bright future.

A display panel based on the quantum dot light-emitting diode (QLED) is similar to an organic light-emitting diode (OLED) display, and the both adopt an overlapped structure as a sandwich. Wherein, a light-emitting of the QLED display panel adopts quantum dots to replace an organic light-emitting material of OLED display to overcome the drawbacks of the organic light-emitting material such as sensitive to water and oxygen and poor stability.

Currently, the manufacturing method for QLED includes spin coating, ink jet printing, and contact transfer printing, the best method to manufacture a full color QLED device is using the ink jet printing. However, the ink jet printing for manufacturing the QLED has some drawbacks: (1) requiring one photolithography process to form pixel grooves, and the cost is higher; (2) the electrical conductivity of anode formed by printing is not high such that the luminescent property of the device is poor.

### SUMMARY OF THE INVENTION

The present invention provides a manufacturing method for an LED display panel and an LED display panel, which can simplify the manufacturing process and effectively increase the production yield.

The present invention provides a manufacturing method for an LED display panel, comprising: forming a first electrode on a substrate; forming a function layer on the first electrode; through a nanoimprint method, forming multiple grooves on a surface of the function layer away from the first electrode; filling a luminescent solution in the multiple grooves in order to form an organic light-emitting layer; and forming a second electrode on the organic light-emitting layer.

Wherein, the first electrode is an anode, the function layer is a hole transport layer and the second electrode is a cathode.

Wherein, the first electrode is a cathode, the function layer is a hole blocking layer and the second electrode is an anode.

Wherein, the first electrode is a cathode, the function layer is an electron transport layer and the second electrode is an anode.

Wherein, the luminescent solution includes a red, a green and a blue quantum dot solutions.

Wherein, each of the red, green and blue quantum dot solutions is made of a hydrophobic material, and the function layer is made of a hydrophilic material.

Wherein, the anode is made of a high conductivity material including indium tin oxide or silver.

Wherein, the method further comprises: forming a hole blocking layer between the organic light-emitting layer and the cathode and/or forming an electron transport layer between the hole blocking layer and the cathode.

Wherein, the method further comprises: forming an electron transport layer between the cathode and the hole blocking layer and/or forming a hole transport layer between the organic light-emitting layer and the anode.

Wherein, the method further comprises: forming an hole blocking layer between the cathode and the electron transport layer and/or forming a hole transport layer between the organic light-emitting layer and the anode.

The present invention also provides an LED display panel, comprising: a first electrode formed on a substrate; a function layer formed on the first electrode; an organic light-emitting layer, formed by filling a luminescent solution in the multiple grooves formed through a nanoimprint method on a surface of the function layer away from the first electrode; and a second electrode formed on the organic light-emitting layer.

Wherein, the first electrode is an anode, the function layer is a hole transport layer and the second electrode is a cathode.

Wherein, the first electrode is a cathode, the function layer is a hole blocking layer and the second electrode is an anode.

Wherein, the first electrode is a cathode, the function layer is an electron transport layer and the second electrode is an anode.

Wherein, the luminescent solution includes a red, a green and a blue quantum dot solutions.

Wherein, each of the red, green and blue quantum dot solutions is made of a hydrophobic material, and the function layer is made of a hydrophilic material.

Wherein, the anode is made of a high conductivity material including indium tin oxide or silver.

Wherein, the display panel further comprises: a hole blocking layer formed between the organic light-emitting layer and the cathode and/or an electron transport layer formed between the hole blocking layer and the cathode.

Wherein, the display panel further comprises: an electron transport layer formed between the cathode and the hole blocking layer and/or a hole transport layer formed between the organic light-emitting layer and the anode.

Wherein, the display panel further comprises: an hole blocking layer formed between the cathode and the electron transport layer and/or a hole transport layer formed between the organic light-emitting layer and the anode.

Comparing to the conventional art, in the present invention, through an ink-jet printing, filling luminescent solution in a preset grooves once formed by adopting a nanoimprint technology in order to form the organic light-emitting layer. The grooves do not require to be formed through photolithography processes of coating, exposure and development, which can simplify the manufacturing process and effectively increase the production yield.

### BRIEF DESCRIPTION OF THE DRAWINGS

In order to more clearly illustrate the technical solution in the present invention or in the prior art, the following will illustrate the figures used for describing the embodiments or the prior art. It is obvious that the following figures are only some embodiments of the present invention. For the person of ordinary skill in the art without creative effort, it can also obtain other figures according to these figures.

FIG. 1 is a cross-sectional view of an LED display panel according to a first embodiment of the present invention;

FIG. 2 is a schematic diagram of the multiple grooves on the hole transport layer of the LED display panel according to the present invention;

FIG. 3 is a cross-sectional view of an LED display panel according to a second embodiment of the present invention;

FIG. 4 is a cross-sectional view of an LED display panel according to a third embodiment of the present invention; and

FIG. 5a-FIG. 5g are schematic cross-sectional views of the manufacturing process of the LED display panel according to a first embodiment of the present invention.

### DETAILED DESCRIPTION OF THE PREFERRED EMBODIMENT

The following content combines with the drawings and the embodiment for describing the present invention in detail. It is obvious that the following embodiments are only some embodiments of the present invention. For the person of ordinary skill in the art without creative effort, the other embodiments obtained thereby are still covered by the present invention.

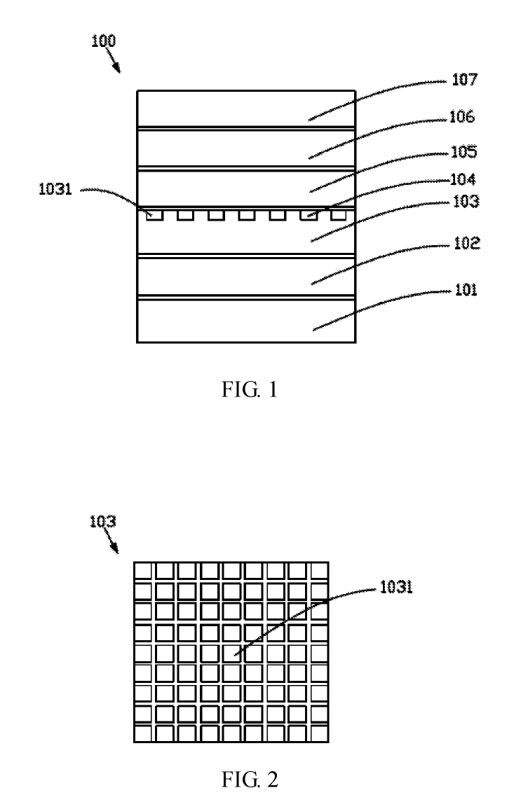

With reference to FIG. 1, an LED (Light Emitting Diode) display panel 100 according to a first embodiment of the present invention is shown. The display panel 100 includes a substrate 101, an anode 102, a hole transport layer 103, an organic light-emitting layer 104, a hole blocking layer 105, an electron transport layer 106 and a cathode 107 which are overlapped. Wherein, a surface of the hole transport layer 103 away from the anode 102 is provided with multiple grooves 1031 formed through a nanoimprint method. A luminescent solution drops in the multiple grooves 1031 until the luminescent solution fully fills the multiple grooves 1031 in order to form the organic light-emitting layer 104. The substrate 101 is usually made of glass. In the present embodiment, the luminescent solution preferably includes a red (R) quantum dot solution, a green (G) quantum dot solution, and a blue (B) quantum dot solution. Because the display panel 100 is a quantum dot light-emitting diode (QLED) display panel, the display panel 100 has advantages of wide color gamut, high color purity, low energy consumption, low cost and good stability. The anode 102 is preferably made of a high electrical conductivity material such as indium tin oxide or silver in order to prevent that the electrical conductivity is not high enough so as to affect the luminescent property of the display panel 100.

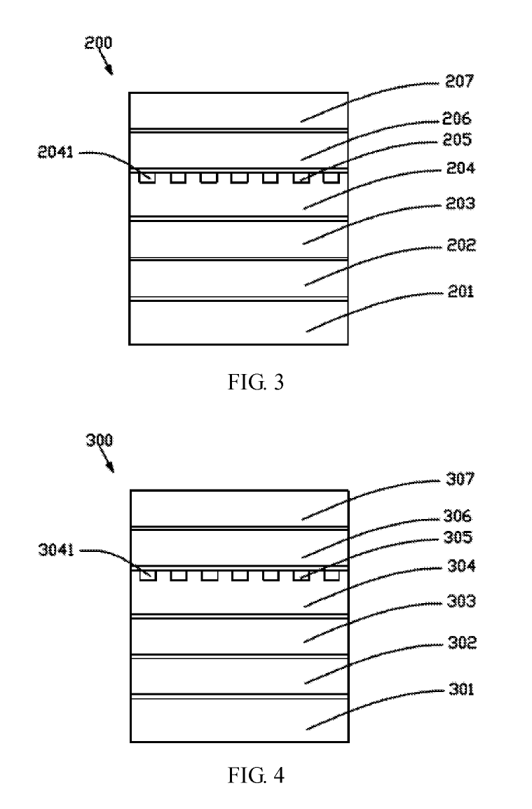

With reference to FIG. 2, which is a schematic diagram of the multiple grooves 1031 on the hole transport layer 103 of the LED display panel according to the present invention. The multiple grooves 1031 are once formed through the nanoimprinting method. Specifically, the multiple grooves 1031 are formed on the hole transport layer 103 by imprinting proportionally through a template having a nano-pattern. Through avoid using expensive light source and optical projection system, the nanoimprint method greatly decreases the cost comparing to the traditional photolithographic method, and the nanoimprint method will not be limited by a physical limitation of a minimum exposure wavelength in the photolithographic method.

Preferably, each of the red, green and blue quantum dot solutions is made of a hydrophobic material, and the hole transport layer 103 is made of a hydrophilic material such as an aqueous solution of poly (3,4-ethylene dioxythiophene)-polystyrene sulfonic acid (PEDOT:PSS). Because of the repulsion effect between the hydrophobic material and the hydrophilic material, a color mixing of the quantum dot solutions in adjacent grooves can be avoided in order to increase the product yield.

In the above structure, when a driving voltage is applied to the anode 102 and the cathode 107, holes injected at the anode 102 applied with an anode voltage move to the organic light-emitting layer 104 through the hole transport layer 103. At the same time, electrons are injected to the organic light-emitting layer 104 from the cathode 107 applied with a cathode voltage after passing through the electron transport layer 106. The electrons and the holes are combined at the organic light-emitting layer 104 in order to generate excitons. Along the excitons change from an excited state to a ground state, fluorescent molecules in the organic light-emitting layer 104 emit light in order to display an image. Wherein, the function of the hole transport layer 103 and the electron transport layer 106 is to control the movement of the holes and the electrons in a fixed direction in order to increase the luminous efficiency of the display panel. The hole blocking layer 105 can limit the movement of the hole injected at the anode 102 in order to balance the carrier and preventing the holes from injecting to the cathode so as to form a leakage current.

It should be noted that in another embodiment of the present invention, without affecting the performance of the LED display panel 100, locations of the hole blocking layer 105 and/or the electron transport layer 106 in the LED display panel 100 can be exchanged. Besides, the hole blocking layer 105 and/or the electron transport layer 106 in the LED display panel 100 can be omitted.

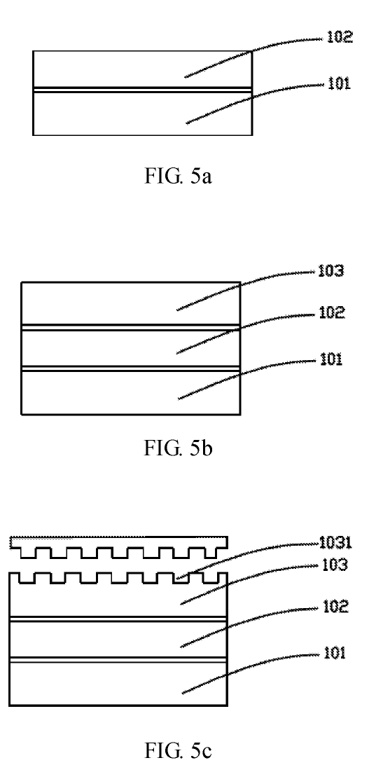

With reference to FIG. 3, a LED (Light Emitting Diode) display panel 200 according to a second embodiment of the present invention is shown. The display panel 200 includes a substrate 201, a cathode 202, an electron transport layer 203, a hole blocking layer 204, an organic light-emitting layer 205, a hole transport layer 206 and an anode 207 which are overlapped. Wherein, a surface of the hole blocking layer 204 away from the cathode 202 is provided with multiple grooves 2041 formed through a nanoimprint method. A luminescent solution drops in the multiple grooves 2041 until the luminescent solution fully fills the multiple grooves 2041 in order to form the organic light-emitting layer 205. The substrate 201 is usually made of glass. In the present embodiment, the luminescent solution preferably includes a red (R) quantum dot solution, a green (G) quantum dot solution, and a blue (B) quantum dot solution. Because the display panel 200 is a quantum dot light-emitting diode (QLED) display panel, the display panel 200 has advantages of wide color gamut, high color purity, low energy consumption, low cost and good stability. The anode 207 is preferably made of a high electric conductivity material such as indium tin oxide or silver in order to prevent that the electric conductivity is not high enough so as to affect the luminescent property of the display panel 200.

Preferably, each of the red, green and blue quantum dot solutions is made of a hydrophobic material, and the hole blocking layer 204 is made of a hydrophilic material. Because of the repulsion effect between the hydrophobic material and the hydrophilic material, a color mixing of the quantum dot solutions in adjacent grooves can be avoided in order to increase the product yield.

In the above structure, when a driving voltage is applied to the cathode 202 and the anode 207, holes injected at the anode 207 applied with an anode voltage move to the organic light-emitting layer 205 through the hole transport layer 206. At the same time, electrons are injected to the organic light-emitting layer 205 from the cathode 202 applied with a cathode voltage after passing through the electron transport layer 203. The electrons and the holes are combined at the organic light-emitting layer 205 in order to generate excitons. Along the excitons change from an excited state to a ground state, fluorescent molecules in the organic light-emitting layer 205 emit light in order to display an image. Wherein, the function of the hole transport layer 206 and the electron transport layer 203 is to control the movement of the holes and the electrons in a fixed direction in order to increase the luminous efficiency of the display panel 200. The hole blocking layer 204 can limit the movement of the hole injected at the anode 202 in order to balance the carrier and preventing the holes from injecting to the cathode so as to form a leakage current.

It should be noted that in another embodiment of the present invention, without affecting the performance of the LED display panel 200, the hole transport layer 206 and/or the electron transport layer 203 in the LED display panel 200 can be omitted.

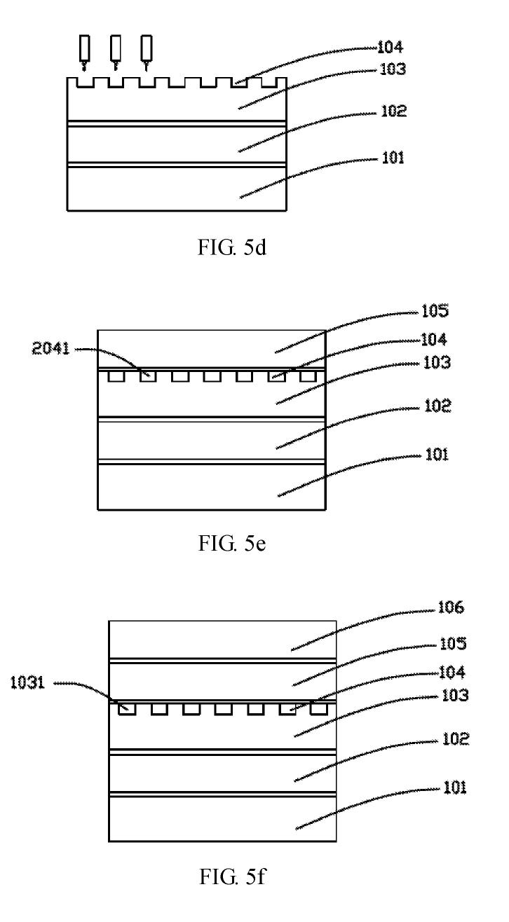

With reference to FIG. 4, an LED (Light Emitting Diode) display panel 300 according to a third embodiment of the present invention is shown. The display panel 300 includes a substrate 301, a cathode 302, a hole blocking layer 303, an electron transport layer 304, an organic light-emitting layer 305, a hole transport layer 306, and an anode 307 which are overlapped. Wherein, a surface of the electron transport layer 304 away from the cathode 302 is provided with multiple grooves 3041 formed through a nanoimprint method. A luminescent solution drops in the multiple grooves 3041 until the luminescent solution fully fills the multiple grooves 3041 in order to form the organic light-emitting layer 305. The substrate 301 is usually made of glass. In the present embodiment, the luminescent solution preferably includes a red (R) quantum dot solution, a green (G) quantum dot solution, and a blue (B) quantum dot solution. Because the display panel 300 is a quantum dot light emitting diode (QLED) display panel, the display panel 300 has advantages of wide color gamut, high color purity, low energy consumption, low cost and good stability. The anode 307 is preferably made of a high electric conductivity material such as indium tin oxide or silver in order to prevent that the electric conductivity is not high enough so as to affect the luminescent property of the display panel 300.

Preferably, each of the red, green and blue quantum dot solutions is made of a hydrophobic material, and the electron transport layer 304 is made of a hydrophilic material. Because of the repulsion effect between the hydrophobic material and the hydrophilic material, a color mixing of the quantum dot solutions in adjacent grooves can be avoided in order to increase the product yield.

In the above structure, when a driving voltage is applied to the cathode 302 and the anode 307, holes injected at the anode 307 applied with an anode voltage move to the organic light-emitting layer 305 through the hole transport layer 306. At the same time, electrons are injected to the organic light-emitting layer 305 from the cathode 302 applied with a cathode voltage after passing through the electron transport layer 304. The electrons and the holes are combined at the organic light-emitting layer 305 in order to generate excitons. Along the excitons change from an excited state to a ground state, fluorescent molecules in the organic light-emitting layer 305 emit light in order to display an image. Wherein, the function of the hole transport layer 306 and the electron transport layer 304 is to control the movement of the holes and the electrons in a fixed direction in order to increase the luminous efficiency of the display panel.

It should be noted that in another embodiment of the present invention, without affecting the performance of the LED display panel 300, the hole transport layer 306 and/or the hole blocking layer 303 in the LED display panel 300 can be omitted.

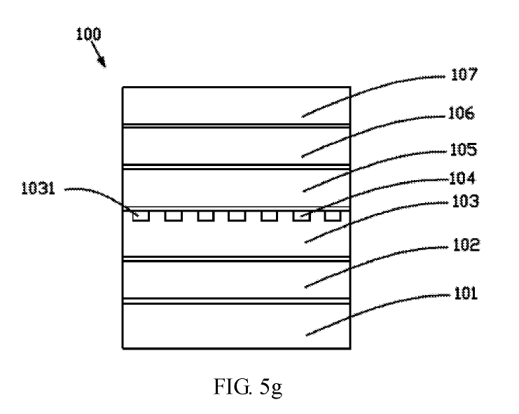

With reference to FIG. 5a-FIG. 5g, schematic cross-sectional views of the manufacturing process of the LED display panel 100 according to a first embodiment of the present invention are shown. With reference to FIG. 5a, in a first step, adopting a sputtering method for sputtering indium tin oxide (ITO) on a substrate 101 or adopting a vapor deposition method for depositing metal silver on the substrate 101 in order to fabricate an anode 102; with reference to FIG. 5b, in a second step, fabricating a hole transport layer (HTL) 103 on the anode 102 through a spin coating method, a thickness of the hole transport layer 103 is about 50 nm; with reference to FIG. 5c, in a third step, adopting a nanoimprinting method, printing out multiple grooves 1031 having a thickness about 30 nm on a surface of the hole transport layer 103 away from the anode 102, wherein, the multiple grooves 1031 are formed on the hole transport layer 103 by imprinting proportionally through a template having a nano-pattern. Through avoid using expensive light source and optical projection system, the nanoimprint method greatly decreases the cost comparing to the traditional photolithographic method, and the nanoimprint method will not be limited by a physical limitation of a minimum exposure wavelength in the photolithographic method.

With reference to FIG. 5d, in a fourth step, adopting an ink-jet printing method to drop a red, a green and a blue quantum dot solutions in the grooves 1031 until the grooves 1031 are fully filled in order to form the organic light-emitting layer 104; with reference to FIG. 5e, adopting a vapor deposition method for depositing a hole blocking layer (HBL) 105 on the organic light-emitting layer 104; with reference to FIG. 5f, in a sixth step, adopting a vapor deposition method to form an electron transport layer (ETL) 106 on the hole blocking layer 105; with reference to FIG. 5g, in a seventh step, adopting a vapor deposition method to form a cathode 107 on the electron transport layer (ETL) 106.

It should be noted that, the LED display panel 200 according to the second embodiment of the present invention and the LED display panel 300 according to the third embodiment of the present invention can be manufactured referring to the above manufacturing processes. Besides, each step in the above manufacturing process can be another more suitable method, and each layer can be another structure beneficial for improving the performance of the LED display panel.

The above embodiment does not constitute a limitation of the scope of protection of the present technology solution. Any modifications, equivalent replacements and improvements based on the spirit and principles of the above embodiments should also be included in the protection scope of the present technology solution.

What is claimed is:

1. A manufacturing method for an LED display panel, comprising:
forming a first electrode on a substrate;
forming a function layer on the first electrode;
through a nanoimprint method, forming multiple grooves on a surface of the function layer away from the first electrode;
filling a luminescent solution in the multiple grooves in order to form an organic light-emitting layer; and
forming a second electrode on the organic light-emitting layer.

2. The manufacturing method for an LED display panel according to claim 1, wherein, the first electrode is an anode, the function layer is a hole transport layer and the second electrode is a cathode.

3. The manufacturing method for an LED display panel according to claim 1, wherein, the first electrode is a cathode, the function layer is a hole blocking layer and the second electrode is an anode.

4. The manufacturing method for an LED display panel according to claim 1, wherein, the first electrode is a cathode, the function layer is an electron transport layer and the second electrode is an anode.

5. The manufacturing method for an LED display panel according to claim 1, wherein, the luminescent solution includes a red, a green and a blue quantum dot solutions.

6. The manufacturing method for an LED display panel according to claim 5, wherein, each of the red, green and blue quantum dot solutions is made of a hydrophobic material, and the function layer is made of a hydrophilic material.

7. The manufacturing method for an LED display panel according to claim 6, wherein, the anode is made of a high conductivity material including indium tin oxide or silver.

8. The manufacturing method for an LED display panel according to claim 2, wherein, the method further comprises: forming a hole blocking layer between the organic light-emitting layer and the cathode and/or forming an electron transport layer between the hole blocking layer and the cathode.

9. The manufacturing method for an LED display panel according to claim 3, wherein, the method further comprises: forming an electron transport layer between the cathode and the hole blocking layer and/or forming a hole transport layer between the organic light-emitting layer and the anode.

10. The manufacturing method for an LED display panel according to claim 4, wherein, the method further comprises: forming an hole blocking layer between the cathode and the electron transport layer and/or forming a hole transport layer between the organic light-emitting layer and the anode.

11. An LED display panel, comprising:
a first electrode formed on a substrate;
a function layer formed on the first electrode;
an organic light-emitting layer, formed by filling a luminescent solution in the multiple grooves formed through a nanoimprint method on a surface of the function layer away from the first electrode; and
a second electrode formed on the organic light-emitting layer.

12. The LED display panel according to claim 11, wherein, the first electrode is an anode, the function layer is a hole transport layer and the second electrode is a cathode.

13. The LED display panel according to claim 11, wherein, the first electrode is a cathode, the function layer is a hole blocking layer and the second electrode is an anode.

14. The LED display panel according to claim 11, wherein, the first electrode is a cathode, the function layer is an electron transport layer and the second electrode is an anode.

15. The LED display panel according to claim 11, wherein, the luminescent solution includes a red, a green and a blue quantum dot solutions.

16. The LED display panel according to claim 15, wherein, each of the red, green and blue quantum dot solutions is made of a hydrophobic material, and the function layer is made of a hydrophilic material.

17. The LED display panel according to claim 16, wherein, the anode is made of a high conductivity material including indium tin oxide or silver.

18. The LED display panel according to claim 12, wherein, the display panel further comprises: a hole blocking layer formed between the organic light-emitting layer and the cathode and/or an electron transport layer formed between the hole blocking layer and the cathode.

19. The LED display panel according to claim 13, wherein, the display panel further comprises: an electron transport layer formed between the cathode and the hole blocking layer and/or a hole transport layer formed between the organic light-emitting layer and the anode.

20. The LED display panel according to claim 14, wherein, the display panel further comprises: an hole blocking layer formed between the cathode and the electron transport layer and/or a hole transport layer formed between the organic light-emitting layer and the anode.
